(19) United States
(12) Patent Application Publication
(10) Pub. No.: US 2024/0202806 A1
(43) Pub. Date: Jun. 20, 2024

(54) DETERMINING AN ARRANGEMENT OF LIGHT UNITS BASED ON IMAGE ANALYSIS

(71) Applicant: SIGNIFY HOLDING B.V., EINDHOVEN (NL)

(72) Inventors: BERNT WILLEM MEERBEEK, VELDHOVEN (NL); BARTEL MARINUS VAN DE SLUIS, EINDHOVEN (NL); MARCELLINUS PETRUS CAROLUS MICHAEL KRIJN, EINDHOVEN (NL); LEENDERT TEUNIS ROZENDAAL, VALKENSWAARD (NL)

(21) Appl. No.: 17/605,901

(22) PCT Filed: Apr. 23, 2020
(86) PCT No.: PCT/EP2020/061305

§ 371 Date: Apr. 13, 2022

(30) Foreign Application Priority Data
Apr. 25, 2019 (EP) 19171111.8

(51) Int. Cl. G06Q 30/0601

(52) U.S. Cl. CPC G06Q 30/0643

(57) ABSTRACT

A system (1) is configured to obtain one or more images captured by a camera and perform image analysis on the one or more images to determine one or more surface properties, including surface dimensions, of one or more surfaces in an environment captured by the one or more images. The system is further configured to select a surface (63) on which a plurality of light units can be placed together based on the surface dimensions. The surface is selected from the one or more surfaces. The system is also configured to determine an arrangement (67) of the plurality of light units on the surface based at least on the surface dimensions of the surface and use at least one output interface (9) to output the arrangement.

### FIELD OF THE INVENTION

The invention relates to a system for determining a lighting design based on an image captured by a camera, said image capturing an environment.

The invention further relates to a method of determining a lighting design based on an image captured by a camera, said image capturing an environment.

The invention also relates to a computer program product enabling a computer system to perform such a method.

### BACKGROUND OF THE INVENTION

Consumers typically visit a bricks and mortar store or browse through the catalogue of an online store to select the lighting devices that appeal to them and that suit their houses. Since there are many lighting devices to choose from, systems have been invented to help consumers make this selection.

For example, US 2015/0278896 A1 discloses a method that assists a user in selecting a lighting device design by providing a lighting device design based on a model or image of a lighting device design (e.g. the user uploading an image of an existing lighting device in his/her home). The lighting device design of the model or image is analyzed in order to determine a lighting device design related variable (e.g. type, shape or color of lighting device design). This variable is then used to select a lighting device design from a set of lighting device designs or to generate a lighting device design. In an embodiment, the lighting design related variable depends on a position where the lighting device design can be placed.

With the advancements in LED, connectivity, battery technology, wireless power, and electronics, increasingly more complex luminaires and lighting systems are being sold. These more complex luminaires and lighting systems typically comprise multiple light modules, in different shapes, which are easy to place in a wide variety of arrangements. These emerging modular lighting arrays enable the creation of richer lighting experiences. Users can get different shapes of light modules and can place the light modules in different arrangements.

However, it may be difficult for people to know which shape of light module they need to buy and/or how to physically arrange the light modules to get to the lighting experience they need or desire. Choosing a lighting design therefore becomes more than just choosing lighting devices and becomes even more difficult for consumers.

### SUMMARY OF THE INVENTION

It is a first object of the invention to provide a system, which assists a user in selecting an arrangement of light units.

It is a second object of the invention to provide a method, which assists a user in selecting an arrangement of light units.

In a first aspect of the invention, a system for determining a lighting design based on an image captured by a camera, said image capturing an environment, comprises at least one input interface, at least one output interface, and at least one processor configured to use said at least one input interface to obtain one or more images captured by said camera, perform image analysis on said one or more images to determine one or more surface properties of one or more surfaces in said environment, said one or more surface properties including surface dimensions, select a surface on which a plurality of light units can be placed together based on said surface dimensions, said surface being selected from said one or more surfaces, determine an arrangement of said plurality of light units on said surface based at least on said surface dimensions of said surface, and use said at least one output interface to output said arrangement.

By using image analysis to determine surface dimensions, selecting a surface on which a plurality of light units can be placed together based on the surface dimensions and determining an arrangement of the plurality of light units on the surface based on the surface dimensions, a user can be assisted in choosing an arrangement of the plurality of light units. The number of light units to be placed together may be specified in advance or may be determined based on the surface dimensions. However, in both cases, the plurality of light units is placed on the same surface to create a richer lighting experience. The arrangement may be part of a configuration, which may further include one or more types, e.g. shapes, of light units and/or a quantity of light units.

Each of said plurality of light units may be a light module, e.g. a tile, and said light modules may be interconnectable. In this case, said at least one processor may be configured to determine a location for a master module of said light modules in said arrangement relative to said surface based on one or more specified limitations for said location. For example, the master module may be the only module that is connected to a power socket and the other modules may rely on the master module for their power. The master module would then need to be located within a certain distance of a power socket and may even be located at the position of the power socket such that it covers and thus hides the power socket and/or power cable from sight. The one or more limitations may be specified by a user or by the system (heuristics), for example.

Said one or more surface properties may further include a surface shape and said at least one processor may be configured to select said surface further based on said surface shape and/or determine types of said plurality of light units based on said surface shape. For example, if a user has already purchased round light units, then a round surface shape may provide the best lighting experience, or if a user has a large round surface that is unoccupied, then round light units may provide the best lighting experience.

Said at least one processor may be configured to determine a quantity of said plurality of light units based on said one or more surface properties. An arrangement of light units that covers a sufficient area of the surface typically provides the best lighting experience. The quantity typically depends on the surface dimensions and the dimensions of the light units.

Said one or more surface properties may further include a surface orientation and said at least one processor may be configured to determine types of said plurality of light units based on said surface orientation. This allows a wall lamp to be selected for a wall surface, a table lamp or standing lamp to be selected for a table or floor surface and a ceiling lamp to be selected for a ceiling surface, for example.

Said at least one processor may be configured to determine a quantity, types and/or said arrangement of said plurality of light units based on a user preference and/or user information and/or a room type. Even if a user has already purchased all his light units, then multiple alternative arrangements may typically still be feasible on a single selected surface. If a user has not yet purchased all his light units, then even more arrangements are feasible on a single selected surface, as the quantity and/or types of light units can still be selected. To make an automatic selection from the multiple arrangements, and if necessary from multiple possible quantities and/or types of light units (i.e. from multiple configurations), user preference, user information and/or room type may be used.

Said at least one processor may be configured to use said at least one input interface to receive user input identifying a quantity and/or types of said plurality of light units and determine said arrangement based on said identified quantity and/or types of said plurality of light units. This is beneficial if the user has already purchased some of his light units or all his light units.

Said at least one processor may be configured to control one or more of said plurality of light units to render a light effect, said one or more light units having been placed on said surface and said light effect indicating where and/or how on said surface a next one of said plurality of light units should be placed. This makes it easier for a user to place the light units on the surface. Instead of looking at a screen or printed paper for directions on where to place all the light units, the user may only need to look at the screen or printed paper for directions on where to place the first light unit and then to the placed light unit(s) for easier-to-follow directions on where to place the next light unit(s).

Said at least one processor may be configured to use said at least one input interface to obtain a first of said one or more images, perform said image analysis on said first image to determine one or more surface properties of one or more first surfaces, select a first surface of said one or more first surfaces on which said plurality of light units can be placed together, allow a user to reject said selected first surface, use said at least one input interface to obtain a second of said one or more images, perform said image analysis on said second image to determine one or more surface properties of one or more second surfaces, select a second surface of said one or more second surfaces on which said plurality of light units can be placed together, and allow a user to accept said selected second surface. This is beneficial, because the user may only need to capture images of surfaces that he thinks are likely suitable. The user can stop capturing images when a suitable surface has been found. As an alternative to this approach, the user may first capture images of a large portion of the environment, e.g. by walking around his house or office with his mobile device's camera activated, and let the system select the most suitable surface after he has finished capturing.

Said at least one processor may be configured to use said at least one output interface to superimpose a visualization of said arrangement of said plurality of light units on a view of said selected surface. This augmented reality approach allows a user to get a good idea of what the arrangement would look like on the targeted surface. If the user does not like the arrangement, he may be able to ask the system to determine another arrangement, e.g. on the same surface or on another surface.

Said one or more surface properties may further include a type of said surface and said at least one processor may be configured to determine a percentage of said surface which may be covered based on said type of said surface and select said surface from said one or more surfaces further based on said determined percentage. For example, if the surface is a table surface, then it is typically desirable to leave sufficient space unoccupied to allow other items to be placed on the table as well.

In a second aspect of the invention, a method of determining a lighting design based on an image captured by a camera, said image capturing an environment, comprises obtaining one or more images captured by said camera, performing image analysis on said one or more images to determine one or more surface properties of one or more surfaces in said environment, said one or more surface properties including surface dimensions, selecting a surface on which a plurality of light units can be placed together based on said surface dimensions, said surface being selected from said one or more surfaces, determining an arrangement of said plurality of light units on said surface based on said surface dimensions of said surface, and outputting said arrangement. Said method may be performed by software running on a programmable device. This software may be provided as a computer program product.

Moreover, a computer program for carrying out the methods described herein, as well as a non-transitory computer readable storage-medium storing the computer program are provided. A computer program may, for example, be downloaded by or uploaded to an existing device or be stored upon manufacturing of these systems.

A non-transitory computer-readable storage medium stores at least one software code portion, the software code portion, when executed or processed by a computer, being configured to perform executable operations for determining a lighting design based on an image captured by a camera, said image capturing an environment.

The executable operations comprise obtaining one or more images captured by said camera, performing image analysis on said one or more images to determine one or more surface properties of one or more surfaces in said environment, said one or more surface properties including surface dimensions, selecting a surface on which a plurality of light units can be placed together based on said surface dimensions, said surface being selected from said one or more surfaces, determining an arrangement of said plurality of light units on said surface based on said surface dimensions of said surface, and outputting said arrangement.

As will be appreciated by one skilled in the art, aspects of the present invention may be embodied as a device, a method or a computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit”, “module” or “system.” Functions described in this disclosure may be implemented as an algorithm executed by a processor/microprocessor of a computer. Furthermore, aspects of the present invention may take the form of a computer program product embodied in one or more computer readable medium(s) having computer readable program code embodied, e.g., stored, thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples of a computer readable storage medium may include, but are not limited to, the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of the present invention, a computer readable storage medium may be any tangible medium that can contain, or store, a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber, cable, RF, etc., or any suitable combination of the foregoing. Computer program code for carrying out operations for aspects of the present invention may be written in any combination of one or more programming languages, including an object oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems), and computer program products according to embodiments of the present invention. It will be understood that each block of the flowchart illustrations and/or block diagrams, and combinations of blocks in the flowchart illustrations and/or block diagrams, can be implemented by computer program instructions. These computer program instructions may be provided to a processor, in particular a microprocessor or a central processing unit (CPU), of a general purpose computer, special purpose computer, or other programmable data processing apparatus to produce a machine, such that the instructions, which execute via the processor of the computer, other programmable data processing apparatus, or other devices create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the figures illustrate the architecture, functionality, and operation of possible implementations of devices, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

### BRIEF DESCRIPTION OF THE DRAWINGS

These and other aspects of the invention are apparent from and will be further elucidated, by way of example, with reference to the drawings, in which:

FIG. 1 is a block diagram of a first embodiment of the system;

FIG. 2 is a block diagram of a second embodiment of the system;

FIG. 3 shows an example of a user interface for the mobile device of FIG. 1;

FIG. 4 is a flow diagram of a first embodiment of the method;

FIG. 5 is a flow diagram of a second embodiment of the method;

FIG. 6 shows examples of different arrangements of the same quantity of light units;

FIGS. 7 to 9 illustrate the function of the system of FIG. 1 which controls light units to indicate where a next light unit should be placed;

FIG. 10 shows an example of a determined configuration; and

FIG. 11 is a block diagram of an exemplary data processing system for performing the method of the invention.

Corresponding elements in the drawings are denoted by the same reference numeral.

### DETAILED DESCRIPTION OF THE EMBODIMENTS

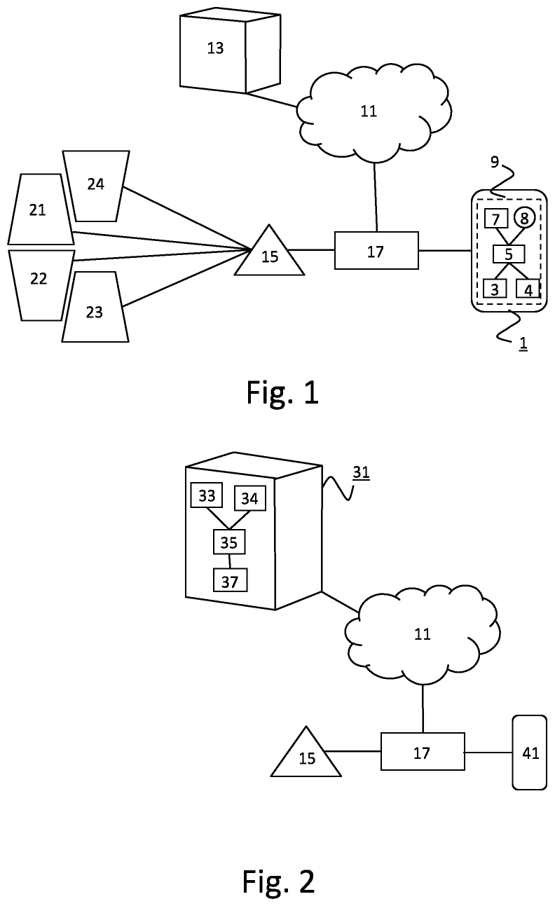

FIG. 1 shows a first embodiment of the system for determining a lighting design based on an image captured by a camera. The image captures an environment. In the embodiment of FIG. 1, the system is a mobile device 1. The mobile device 1 is connected to the Internet (backbone) 11 via a wireless LAN access point 17. An Internet server 13 is also connected to the Internet 11.

The mobile device 1 comprises a receiver 3, a transmitter 4, a processor 5, memory 7, a camera 8 and a display 9. The processor 5 is configured to use the camera 8 to obtain one or more images and perform image analysis on the one or more images to determine one or more surface properties of one or more surfaces in the environment. The one or more surface properties include surface dimensions.

The processor 5 is further configured to select a surface on which a plurality of light units can be placed together based on the surface dimensions. The surface is selected from the one or more surfaces. The processor 5 is also configured to determine an arrangement of the plurality of light units on the surface based at least on the surface dimensions of the surface and use the display 9 to output the arrangement.

In the embodiment of FIG. 1, each of the plurality of light units is a light module, a tile in particular. The light modules may be mechanically and/or electrically interconnectable. Alternatively, the light modules may have their own power supply and communication interface, for example. In the embodiment of FIG. 1, the processor 5 is configured to determine a location for a master module of the light modules relative to the surface based on one or more specified limitations for the location when the purchased or determined type of light modules uses master and slave modules and only the master module(s) needs to be connected to a power socket.

In the example of FIG. 1, four light modules 21-24 have been added to the lighting system. These light modules 21-24 are controlled via a light bridge 15, e.g. using the Zigbee protocol. The light bridge 15 is also connected to the wireless LAN access point 17, e.g. via an Ethernet or Wi-Fi (IEEE 802.11) connection. The light bridge 15 may be a Philips Hue bridge, for example. Five light modules 25-29 (not shown) still need to be added to the lighting system.

In the example of FIG. 1, the light modules 21-29 are tiles and light modules 25-29 are intended to be placed next to light modules 21-24. Alternatively, different types of light modules or non-modular light modules may be used. In the embodiment of FIG. 1, the processor 5 is configured to control one or more of the installed light modules 21-24 to render a light effect that indicates where on the selected surface a next one of the of the light modules should be placed.

In the embodiment of FIG. 1, the user can point his mobile device towards the target location and through computer vision techniques, the properties of the surfaces (typically surface type, surface shape, and surface dimensions) are determined automatically. In an alternative embodiment, instead of having the user capture images, the mobile device 1 has access to (e.g. 3D) images which have been captured before at the target location.

Based on the determined surface properties, the mobile device 1 determines the best matching arrangement for a modular light array and if necessary, e.g. if the user has not already purchased the light modules, the best matching module shape(s). Module shape refers to the shape of the individual light module. Examples are squared, rectangular, triangular, hexagonal, and circular. Arrangement refers to the way the light modules are placed in relation to each other. This can be a horizontal line, vertical line, matrix, star, circle, T-shape, for example.

In the embodiment of FIG. 1, a database with all possible module shapes and arrangements of modular lighting arrays, stored on the Internet server 13, is queried with the parameters derived from the surface properties. Each shape and arrangement has a score how well it fits certain parameters. These scores can be provided by the manufacturer of the products, but also learned from how (other) consumers have used these shapes and arrangements. The best scoring option(s) will be selected.

In the embodiment of the mobile device 1 shown in FIG. 1, the mobile device 1 comprises one processor 5. In an alternative embodiment, the mobile device 1 comprises multiple processors. The processor 5 of the mobile device 1 may be a general-purpose processor, e.g. from ARM or Qualcomm or an application-specific processor. The processor 5 of the mobile device 1 may run an Android or iOS operating system for example. The display 9 may comprise an LCD or OLED display panel, for example. The memory 7 may comprise one or more memory units. The memory 7 may comprise solid state memory, for example. The camera 8 may comprise a CMOS or CCD sensor, for example.

The receiver 3 and the transmitter 4 may use one or more wireless communication technologies such as Wi-Fi (IEEE 802.11) to communicate with the wireless LAN access point 17, for example. In an alternative embodiment, multiple receivers and/or multiple transmitters are used instead of a single receiver and a single transmitter. In the embodiment shown in FIG. 1, a separate receiver and a separate transmitter are used. In an alternative embodiment, the receiver 3 and the transmitter 4 are combined into a transceiver. The mobile device 1 may comprise other components typical for a mobile device such as a battery and a power connector. The invention may be implemented using a computer program running on one or more processors.

In the embodiment of FIG. 1, the system is a mobile device. In an alternative embodiment, the system of the invention is a different device, e.g. a computer. In the embodiment of FIG. 1, the system of the invention comprises a single device. In an alternative embodiment, the system of the invention comprises a plurality of devices. In the embodiment of FIG. 1, a bridge is used to control light modules 21-24. In an alternative embodiment, light modules 21-24 are controlled without using a bridge, e.g. directly by the mobile device 1 using BLE.

FIG. 2 shows a second embodiment of the system for determining a lighting design based on an image captured by a camera. In the embodiment of FIG. 2, the system is a computer 31. The computer is connected to the Internet 11 and acts as a server, e.g. in a cloud environment. The computer 31 replaces the Internet server 13 of FIG. 1. In the example of FIG. 2, no light units have been installed yet.

The computer 31 comprises a receiver 33, a transmitter 34, a processor 35, and storage means 37. The processor 35 is configured to use the receiver 33 to receive one or more images captured by a camera of a mobile device 41 and perform image analysis on the one or more images to determine one or more surface properties of one or more surfaces in the environment captured in the one or more images. The one or more surface properties include surface dimensions.

The processor 35 is further configured to select a surface on which a plurality of light units can be placed together based on the surface dimensions. The surface is selected from the one or more surfaces. The processor 35 is further configured to determine an arrangement of the plurality of light units on the selected surface based at least on the surface dimensions of the surface and use the transmitter 34 to transmit the arrangement to the mobile device 41. The mobile device 41 uses its display to show the arrangement to the user of the mobile device 41.

In the embodiment of the computer 31 shown in FIG. 2, the computer 31 comprises one processor 35. In an alternative embodiment, the computer 31 comprises multiple processors. The processor 35 of the computer 31 may be a general-purpose processor, e.g. from Intel or AMD, or an application-specific processor. The processor 35 of the computer 31 may run a Windows or Unix-based operating system for example. The storage means 37 may comprise one or more memory units. The storage means 37 may comprise one or more hard disks and/or solid-state memory, for example. The storage means 37 may be used to store an operating system, applications and application data, for example.

The receiver 33 and the transmitter 34 may use one or more wired and/or wireless communication technologies such as Ethernet and/or Wi-Fi (IEEE 802.11) to communicate with an access point to the Internet 11, for example. In an alternative embodiment, multiple receivers and/or multiple transmitters are used instead of a single receiver and a single transmitter. In the embodiment shown in FIG. 2, a separate receiver and a separate transmitter are used. In an alternative embodiment, the receiver 33 and the transmitter 34 are combined into a transceiver. The computer 31 may comprise other components typical for a computer such as a power connector and a display. The invention may be implemented using a computer program running on one or more processors.

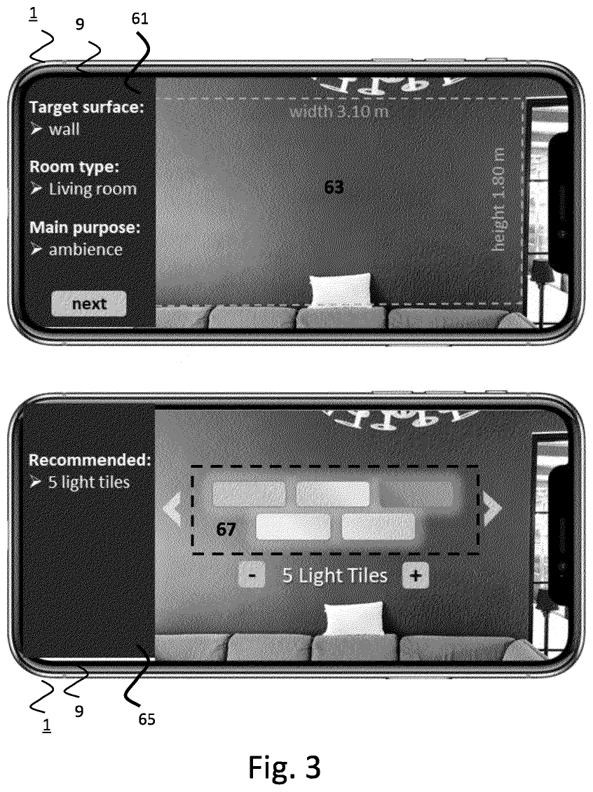

FIG. 3 shows an example of a user interface for the mobile device 1 of FIG. 1. In this example, the user interface is provided by an Augmented Reality (AR) app running on the mobile device 1 and displayed on display 9 of the mobile device 1. When a customer is interested in expanding his lighting system with modular light units, he first points mobile device 1 to the to the surface where he plans to install the light units, e.g. surface 63 of FIG. 3.

Surface properties are automatically determined by using image analysis. In the example of FIG. 3, the surface properties consist of the surface shape (rectangle), surface dimensions (3.10 m width and 1.80 m height) and surface type (wall). The orientation of the surface can be determined from the surface type. For example, a surface type “wall” indicates a vertical orientation and a surface type “floor” or “table” indicates a horizontal orientation.

Via screen 61 of the user interface, the user further specifies the main purpose (“ambience”) of the light units to be installed and the room type (“Living room”). The mobile device 1 may also be able to determine the room type automatically. By pressing a button titled “next”, the collected information is transmitted to an Internet server in the cloud where a subset of best matching configurations is determined and identified in a message that the Internet server transmits to the mobile device 1.

Each configuration comprises a combination of a certain type or certain types of light units, a certain quantity of these light units and a certain arrangement of these light units. The desired quantity of light units is determined based on the surface dimensions. The desired types of light units may be determined based on the desired quantity of light units and the surface dimensions. Alternatively, the desired quantity of light units may be determined based on the desired types of light units and the surface dimensions. The desired types of light units may further be determined based on the surface shape and the surface type/orientation.

A description of a desired type may identify a desired shape, desired dimensions, a desired product category (e.g. standing lamp, desk lamp or ceiling lamp), a desired brand name, and/or a desired model number, for example. The desired arrangement of light units is determined based on the desired types and quantity of light units or the desired types and quantity of light units are determined based on the desired arrangement of light units.

In the example of FIG. 3, the subset of configurations is selected from the set of best matching configurations based on the room type. Additionally or alternatively, the subset of configurations may be selected based on a user preference and/or user information.

The mobile device 1 determines the configurations from the message transmitted by the Internet server and presents them as a browsable list. In an alternative embodiment, the mobile device 1 itself comprises a database of configurations and no information needs to be transmitted to an Internet server.

In the example of FIG. 3, the first configuration in screen 65 of the user interface is an arrangement 67 of five rectangular light tiles and the user is able to increase or decrease the quantity of light tiles manually. In the example of FIG. 3, a visualization of the arrangement of the plurality of light units is superimposed on a view of the selected surface.

In the embodiment of FIG. 1, the mobile device 1 performs the image analysis and selects a surface. In the embodiment of FIG. 2, the computer/Internet server 31 performs the image analysis and selects the surface. The user interface of the app running on the mobile device 41 may look similar to the user interface of the app running on the mobile device 1, as shown in FIG. 3, but instead of the mobile device 1 transmitting the collected information to the Internet server 11 after the button titled “next” is pressed, the mobile device 41 transmits one or more images to the computer/Internet server 31 before the screen 61 is displayed.

The user may additionally be provided with an impression of some of the scenes that are most frequently rendered on the determined configuration of light units, e.g. in augmented reality. The user may be offered the option to accept the recommended configuration or request an alternative configuration in dependence on the user's appreciation of the result.

In the user interface of FIG. 3, the user is not able to indicate whether he has already purchased light units and if so, which ones. In an alternative user interface, the user is able to indicate which light units he has already purchased, and the surface may be selected based on its shape and based on the shapes of the already purchased light units, for example.

A first embodiment of the method of determining a lighting design based on an image captured by a camera is shown in FIG. 4. The image captures an environment. A step 101 comprises obtaining one or more images captured by the camera. A step 103 comprises performing image analysis on the one or more images to determine one or more surface properties of one or more surfaces in the environment. The one or more surface properties include surface dimensions. In the embodiment of FIG. 4, the one or more surface properties further include a type of the surface.

A step 121 comprises determining a percentage of the surface which may be covered based on the type of the surface. A step 105 comprises selecting a surface on which a plurality of light units can be placed together based on the surface dimensions. The surface is selected from the one or more surfaces. In the embodiment of FIG. 4, step 105 comprises a sub step 123. Step 123 comprises selecting the surface from the one or more surfaces based on the surface dimensions and the determined percentage.

A step 107 comprises determining an arrangement of the plurality of light units on the surface based on the surface dimensions of the surface. A step 109 comprises outputting the arrangement.

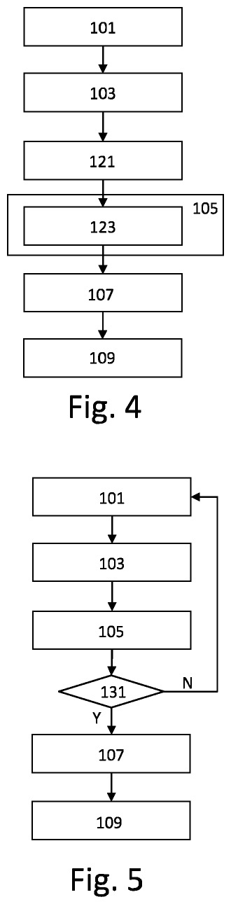

A second embodiment of the method of determining a lighting design based on an image captured by a camera is shown in FIG. 5. Step 101 comprises obtaining one or more images captured by the camera. Step 103 comprises performing image analysis on the one or more images to determine one or more surface properties of one or more surfaces in the environment. The one or more surface properties include surface dimensions.

Step 105 comprises selecting a surface on which a plurality of light units can be placed together based on the surface dimensions. The surface is selected from the one or more surfaces. A step 131 comprises allowing a user to accept or reject the surface selected in step 105. The selected surface may be accepted by pressing a certain real or virtual button, for example. The selected surface may be rejected by pressing another real or virtual button or by capturing another image without accepting the selected surface, for example.

If the selected surface is not accepted in step 131, step 101 is repeated. If the selected surface is accepted in step 131, step 107 is performed next. Step 107 comprises determining an arrangement of the plurality of light units on the surface based on the surface dimensions of the surface. Step 109 comprises outputting the arrangement. In a variation on the embodiment of FIG. 5, a user is asked after step 109 whether he is happy with the arrangement and if he is not, step 101 or step 107 is repeated.

Steps 121 and 123 of FIG. 4 have been omitted in the second embodiment of FIG. 5. In a variation on the second embodiment of FIG. 5, steps 121 and 123 of FIG. 4 have been added. In a variation on the first embodiment of FIG. 4, steps 121 and 123 are omitted.

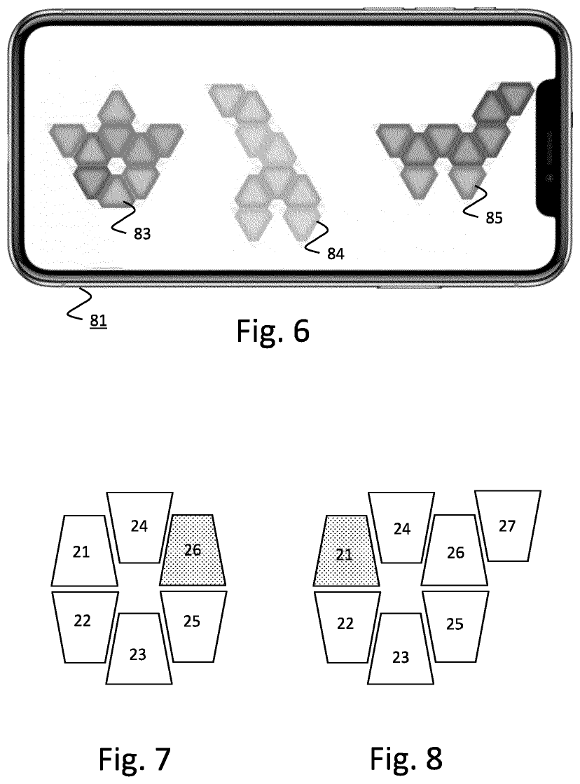

FIG. 6 shows examples of different arrangements of the same quantity of light units. If the user already has purchased a certain quantity of one or more certain types of light units, he may be able to provide user input identifying this quantity and/or these one or more certain types and the arrangement is then determined based on the identified quantity and/or types of the light units. In FIG. 6, three different arrangements 83, 84 and 85 are shown with nine light units of the same type. Arrangements with a larger quantity of this type of light unit could also be shown to give the user an idea of what he could do with additional light units.

An arrangement may include installation instructions specific to this arrangement and the light unit type(s) that it is an arrangement of. These installation instructions may be provided electronically or as hardcopy. In the latter case, the installation instructions may comprise a printed sheet that the user can attach against the wall to ease the installation process (e.g. drawing holes at right location). The printed sheet may also help to give a visual impression (real-size) of the layout on the surface and may be used to finetune the location, or even to reconsider the layout when the arrangement looks different when visualized with its real size, e.g. bigger, than the on-screen impression.

Alternatively, one or more light units already having been placed on the surface may be controlled to render a light effect indicating where and/or how on the surface a next one of the light units should be placed, e.g. by a mobile device. FIGS. 7 to 9 illustrate the function of the system of FIG. 1 which controls light units to indicate where a next light unit should be placed.

In the example of FIG. 7, light units 21-26 have already been placed on the surface and a mobile device activates the light unit 26 to indicate that the next light unit, light unit 27 of FIG. 8, should be placed next to the light unit 26. In the example of FIG. 7, the entire light unit 26 renders light. However, certain light units may be controlled to render a light effect on only one side of the light unit to indicate on which side of the light unit the next light unit should be placed. Alternatively or additionally, certain light units may be controlled to render a light effect that indicates the orientation of the next light unit.

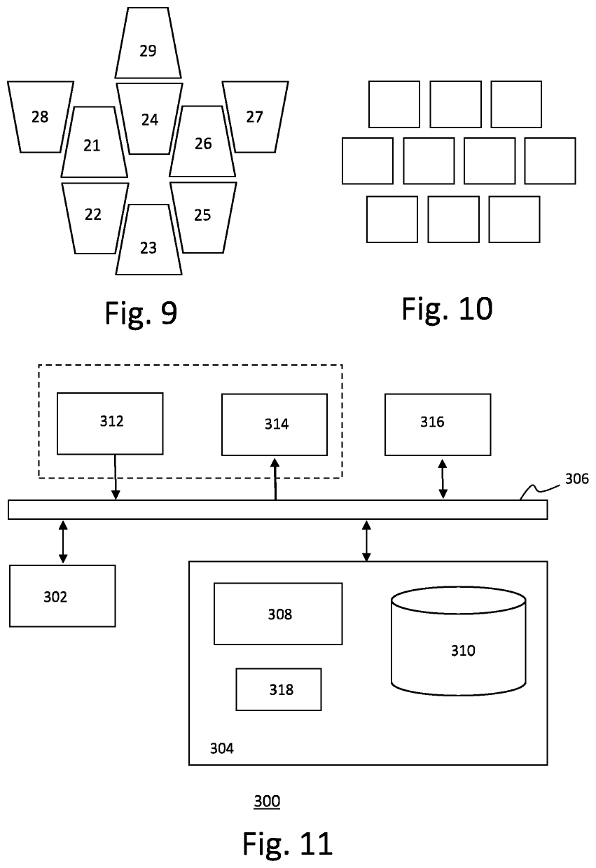

In the example of FIG. 8, light units 21-27 have already been placed on the surface and a mobile device activates the light unit 21 to indicate that the next light unit, light unit 28 of FIG. 9, should be placed next to the light unit 21. In the example of FIG. 9, all light units 21-29 have been placed on the surface.

After all light units have been placed, scenes can be rendered on the light units. These light scenes are preferably optimized for a certain arrangement and indicate settings per light unit. This light content may be retrieved or created. Creation of this new light content can be done using generative content creation algorithms, for example. New light content can also be retrieved from external information sources. For example, a database with annotated images that are associated with particular arrangements of particular light unit types (e.g. particular light unit shapes).

As previously described in relation to FIG. 3, a subset of configurations may be selected from the set of best matching configurations based a user preference and/or user information. User preferences and user information can be retrieved from a variety of sources and may contain different types of information:

### Light Content

Information about the preferred lighting content can be retrieved from historic data on usage of a lighting system, stored light settings/presets, analysis of lighting content carriers like images, similarity to other users' setups (who already have a modular lighting array), or some combination thereof.

In the case of a Philips Hue system, the scene images (and/or their usage data) that are installed on the bridge (or app) may be analyzed and its prominent features or properties may be added to a profile. For example, favorite objects in the images (e.g. animals, sunsets, horizons, cityscapes, etc.), dominant gradient directions (e.g. horizontal vs vertical gradients), and color distributions may be analyzed. These properties may be used to determine arrangements or configurations that will provide an optimal lighting experience for that content. For example, if many images of sunsets on a beach are found, an arrangement with mainly horizontal orientation might be recommended that can best render an impression of a sunset disappearing below a horizon.

### Personal Information

Certain personal information about the user might be retrieved as input for determining an arrangement or configuration. This may include location information (geolocation), gender, age, household composition, for example.

This information may be used to determine a user's expected preferences with respect to certain arrangements or configurations. For example, a 23-year-old female might prefer more organic and flexible light unit shapes and arrangements, while a 57-year-old male might prefer more sleek and formal light unit shapes and arrangements. Similarly, based on geolocation, certain cultural aesthetic preferences might be taken into account. This could be taken into account in a coarse manner (e.g. East-Asia preference for warm/cool light is different from European preference), but also in a fine-grained manner (e.g. neighborhood demographic statistics).

Input related to the user's interior may also be acquired. For instance, images captured at the target location may be analyzed to find specific shapes and patterns in the interior. Furthermore, images may be found of recently bought furniture products, decoration items or artworks, and those images may be analyzed to detect specific shapes. Input related to the user's previous acquisitions (e.g. the Hue lights bought beforehand, or other household items bought such as decorative items) may also be acquired.

### Lighting Infrastructure and Connected Devices

The user information may also contain information about the existing lighting infrastructure and connected devices of the user, e.g. the quantity and type of light units (e.g. luminaires) already installed in the users' home, location information of existing light units, room type, and shape of existing light units and connected devices. Connected devices which are not directly light emitting might nevertheless give useful hints. For example, if the names of some existing light units include “TV” (since they are located near the TV or used in conjunction with TV viewing) and a new modular light array is meant to be mounted in that area, it may be assumed that a TV is present (possibly even detected on the local home network), so the determined configuration and light scenes may be adapted accordingly.

The shape of other light units and other devices a user owns can tell something about his shape preferences. For example, if a user has circular shaped luminaires, it is likely that he would also prefer a circular modular lighting array, while if he has rectangular luminaires, a configuration with rectangular light units arranged in a rectangular shape may be determined.

### Daily Routines and Lighting Usage

The user information might contain information about people's daily routines and lighting usage patterns. For example, some users might be using their space and lighting throughout the day for working at home, while others might use their space and lighting during the evening for relaxation purpose. For the first group, arrangements or configuration suitable for more functional lighting are determined. This could for example include a prescription to orient the light units such that downlighting is provided, to equally distribute the light units such that uniform lighting is created, and to center the light units above working surfaces.

For the second group, arrangements or configurations that are more suitable for decorative purposes are determined. This could for example include a prescription to place the light units on a vertical surface, close to each other, in an organic form. Similarly, users can indicate they want to use the modular lighting array for information purposes (e.g. signage). In this case, an arrangement or configuration might include light units in a matrix arrangement such that the light units can display a broad range of characters or icons.

As previously described, a configuration may comprise one or more types of light units, a quantity of these light units and an arrangement of these light units. The one or more types of light units may indicate the shape and dimensions of these light units, for example. The arrangement may indicate the pattern of the light units and the spacing between the light units, for example.

For instance, the configuration shown in FIG. 10 may be determined given the input below:
Most frequently used scenes: sunsets (arrangements with mainly horizontal orientation get higher scores)
Geolocation: Netherlands (configurations that are popular in the Netherlands get higher scores)
Existing luminaires: Hue Aurelle Square (square shaped tiles get higher scores)
Key lighting need: decorative (arrangements in which the light units are in close proximity get higher scores)
Surface dimensions: 100×100 cm (arrangements that fit nicely on a 100×100 cm surface get higher scores)

FIG. 11 depicts a block diagram illustrating an exemplary data processing system that may perform the method as described with reference to FIGS. 4 and 5.

As shown in FIG. 11, the data processing system 300 may include at least one processor 302 coupled to memory elements 304 through a system bus 306. As such, the data processing system may store program code within memory elements 304. Further, the processor 302 may execute the program code accessed from the memory elements 304 via a system bus 306. In one aspect, the data processing system may be implemented as a computer that is suitable for storing and/or executing program code. It should be appreciated, however, that the data processing system 300 may be implemented in the form of any system including a processor and a memory that is capable of performing the functions described within this specification.

The memory elements 304 may include one or more physical memory devices such as, for example, local memory 308 and one or more bulk storage devices 310. The local memory may refer to random access memory or other non-persistent memory device(s) generally used during actual execution of the program code. A bulk storage device may be implemented as a hard drive or other persistent data storage device. The processing system 300 may also include one or more cache memories (not shown) that provide temporary storage of at least some program code in order to reduce the quantity of times program code must be retrieved from the bulk storage device 310 during execution. The processing system 300 may also be able to use memory elements of another processing system, e.g. if the processing system 300 is part of a cloud-computing platform.

Input/output (I/O) devices depicted as an input device 312 and an output device 314 optionally can be coupled to the data processing system. Examples of input devices may include, but are not limited to, a keyboard, a pointing device such as a mouse, a microphone (e.g. for voice and/or speech recognition), or the like. Examples of output devices may include, but are not limited to, a monitor or a display, speakers, or the like. Input and/or output devices may be coupled to the data processing system either directly or through intervening I/O controllers.

In an embodiment, the input and the output devices may be implemented as a combined input/output device (illustrated in FIG. 11 with a dashed line surrounding the input device 312 and the output device 314). An example of such a combined device is a touch sensitive display, also sometimes referred to as a “touch screen display” or simply “touch screen”. In such an embodiment, input to the device may be provided by a movement of a physical object, such as e.g. a stylus or a finger of a user, on or near the touch screen display.

A network adapter 316 may also be coupled to the data processing system to enable it to become coupled to other systems, computer systems, remote network devices, and/or remote storage devices through intervening private or public networks. The network adapter may comprise a data receiver for receiving data that is transmitted by said systems, devices and/or networks to the data processing system 300, and a data transmitter for transmitting data from the data processing system 300 to said systems, devices and/or networks. Modems, cable modems, and Ethernet cards are examples of different types of network adapter that may be used with the data processing system 300.

As pictured in FIG. 11, the memory elements 304 may store an application 318. In various embodiments, the application 318 may be stored in the local memory 308, the one or more bulk storage devices 310, or separate from the local memory and the bulk storage devices. It should be appreciated that the data processing system 300 may further execute an operating system (not shown in FIG. 11) that can facilitate execution of the application 318. The application 318, being implemented in the form of executable program code, can be executed by the data processing system 300, e.g., by the processor 302. Responsive to executing the application, the data processing system 300 may be configured to perform one or more operations or method steps described herein.

Various embodiments of the invention may be implemented as a program product for use with a computer system, where the program(s) of the program product define functions of the embodiments (including the methods described herein). In one embodiment, the program(s) can be contained on a variety of non-transitory computer-readable storage media, where, as used herein, the expression “non-transitory computer readable storage media” comprises all computer-readable media, with the sole exception being a transitory, propagating signal. In another embodiment, the program(s) can be contained on a variety of transitory computer-readable storage media. Illustrative computer-readable storage media include, but are not limited to: (i) non-writable storage media (e.g., read-only memory devices within a computer such as CD-ROM disks readable by a CD-ROM drive, ROM chips or any type of solid-state non-volatile semiconductor memory) on which information is permanently stored; and (ii) writable storage media (e.g., flash memory, floppy disks within a diskette drive or hard-disk drive or any type of solid-state random-access semiconductor memory) on which alterable information is stored. The computer program may be run on the processor 302 described herein.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of embodiments of the present invention has been presented for purposes of illustration, but is not intended to be exhaustive or limited to the implementations in the form disclosed. Many modifications and variations will be apparent to those of ordinary skill in the art without departing from the scope and spirit of the present invention. The embodiments were chosen and described in order to best explain the principles and some practical applications of the present invention, and to enable others of ordinary skill in the art to understand the present invention for various embodiments with various modifications as are suited to the particular use contemplated.

1. A system for determining a lighting design for a plurality of light units, based on an image captured by a camera, said image capturing an environment, wherein said plurality of light units are mechanically and electrically interconnectable light modules, said system comprising:
at least one input interface;
at least one output interface; and
at least one processor configured to:
use said at least one input interface to obtain one or more images captured by said camera,
perform image analysis on said one or more images to determine one or more surface properties of one or more surfaces in said environment, said one or more surface properties including surface dimensions,
select a surface on which the plurality of light units can be placed together based on said surface dimensions, said surface being selected from said one or more surfaces,
determine a quantity of said plurality of light units based on said one or more surface properties,
determine an arrangement of said plurality of light units on said surface based at least on said surface dimensions of said surface, and
use said at least one output interface to output said arrangement.

2. A system as claimed in claim 1, wherein said light modules are tiles.

3. A system as claimed in claim 1, wherein said at least one processor is configured to determine a location for a master module of said light modules in said arrangement relative to said surface based on one or more specified limitations for said location.

4. A system as claimed in claim 1, wherein said one or more surface properties further include a surface shape and said at least one processor is configured to select said surface further based on said surface shape and/or determine types of said plurality of light units based on said surface shape.

5. A system as claimed in claim 1, wherein said one or more surface properties further include a surface orientation and said at least one processor is configured to determine types of said plurality of light units based on said surface orientation.

6. A system as claimed in claim 1, wherein said at least one processor is configured to determine a quantity, types and/or said arrangement of said plurality of light units based on a user preference and/or user information and/or a room type.

7. A system as claimed in claim 1, wherein said at least one processor is configured to use said at least one input interface to receive user input identifying a quantity and/or types of said plurality of light units and determine said arrangement based on said identified quantity and/or types of said plurality of light units.

8. A system as claimed in claim 1, wherein said at least one processor is configured to control one or more of said plurality of light units to render a light effect, said one or more light units having been placed on said surface and said light effect indicating where and/or how on said surface a next one of said plurality of light units should be placed.

9. A system as claimed in claim 1, wherein said at least one processor is configured to use said at least one input interface to obtain a first of said one or more images, perform said image analysis on said first image to determine one or more surface properties of one or more first surfaces, select a first surface of said one or more first surfaces on which said plurality of light units can be placed together, allow a user to reject said selected first surface, use said at least one input interface to obtain a second of said one or more images, perform said image analysis on said second image to determine one or more surface properties of one or more second surfaces, select a second surface of said one or more second surfaces on which said plurality of light units can be placed together, and allow a user to accept said selected second surface.

10. A system as claimed in claim 1, wherein said at least one processor is configured to use said at least one output interface to superimpose a visualization of said arrangement of said plurality of light units on a view of said selected surface.

11. A system as claimed in claim 1, wherein said one or more surface properties further include a type of said surface and said at least one processor is configured to determine a percentage of said surface which may be covered based on said type of said surface and select said surface from said one or more surfaces further based on said determined percentage.

12. A method of determining a lighting design for a plurality of light units based on an image captured by a camera, said image capturing an environment, wherein said plurality of light units are mechanically and electrically interconnectable light modules, said method comprising:
obtaining one or more images captured by said camera;
performing image analysis on said one or more images to determine one or more surface properties of one or more surfaces in said environment, said one or more surface properties including surface dimensions;
selecting a surface on which said plurality of light units can be placed together based on said surface dimensions, said surface being selected from said one or more surfaces;
determining a quantity of said plurality of light units based on said one or more surface properties;
determining an arrangement of said plurality of light units on said surface based on said surface dimensions of said surface; and
outputting said arrangement.

13. A non-transitory computer program or suite of computer programs comprising at least one software code portion or a computer program product storing at least one software code portion, the software code portion, when run on a computer system, being configured for enabling the method of claim 12 to be performed.
